(19) United States
(12) Patent Application Publication
(10) Pub. No.: US 2021/0166997 A1
(43) Pub. Date: Jun. 3, 2021

(54) SEMICONDUCTOR PACKAGE USING CONDUCTIVE METAL STRUCTURE

(71) Applicant: JMJ Korea Co., Ltd., Bucheon-si, Gyeonggi-do (KR)

(72) Inventors: Yun Hwa CHOI, Bucheon-si, Gyeonggi-do (KR); Soon Seong CHOI, Gunpo-Si, Gyeonggi-do (KR)

(73) Assignee: JMJ Korea Co., Ltd., Bucheon-si, Gyeonggi-do (KR)

(21) Appl. No.: 16/772,800

(22) PCT Filed: Jan. 31, 2019
(86) PCT No.: PCT/KR2019/001322

§ 371 Date: Jun. 14, 2020

(30) Foreign Application Priority Data
Feb. 7, 2018 (KR) 10-2018-0015197
Mar. 13, 2018 (KR) 10-2018-0029167
Jan. 24, 2019 (KR) 10-2019-0009219

(51) Int. Cl. H01L 23/495; H01L 23/00

(52) U.S. Cl. CPC H01L 23/49524; H01L 24/05; H01L 24/32; H01L 24/29; H01L 2224/04026; H01L 2224/30181; H01L 2224/32175; H01L 2224/29111; H01L 2224/29124; H01L 2224/29116; H01L 2224/05624

(57) ABSTRACT

Provided is a semiconductor package using a conductive metal structure, and more particularly, to a semiconductor package using a conductive metal structure formed in a clip or a column, through which a semiconductor chip and a lead of a lead frame are electrically connected to each other and an area where the semiconductor chip and the metal structure are adhered may be effectively improved so that productivity may increase and durability and electrical connection properties may be improved. The semiconductor package according to the present invention includes: a semiconductor chip; an aluminum pad formed on an upper part of the semiconductor chip; and a conductive metal structure adhered to the aluminum pad by a solder-based second adhesive layer, wherein the second adhesive layer includes intermetallic compounds (IMC) distributed to a lower fixed part thereof near the aluminum pad.

### FIELD OF THE INVENTION

The present invention relates to a semiconductor package using a conductive metal structure, and more particularly, to a semiconductor package using a conductive metal structure formed in a clip or a column, through which a semiconductor chip and a lead of a lead frame are electrically connected to each other and an area where the semiconductor chip and the metal structure are adhered may be effectively improved so that productivity may increase and durability and electrical connection properties may be improved.

### DESCRIPTION OF THE RELATED ART

In general, a semiconductor package includes a semiconductor chip, a lead frame (or a board), and a package body, wherein the semiconductor chip is attached on a pad of the lead frame and is electrically connected to a lead of the lead frame by bonding a metal wire.

However, in a stack package using a general metal wire, the metal wire is used to exchange electric signals so that speed is lowered and a large number of wires is used. Accordingly, deterioration on electrical properties may occur in each chip. Also, in order to form metal wires, an additional area is required in a board and thus, a size of a package is enlarged. In addition, gaps used to bond wires are required in bonding pads of each chip and thus, an entire height of a package unnecessarily increases.

Therefore, Korean Patent No. 1208332, Utility Model No. 0482370, Korean Patent No. 1669902, and Korean Patent No. 1631232 disclosed by the inventor of the present invention provide an efficient package structure showing excellent performances in electric connection, heat emission, and thermal stability by using a metal clip structure, compared with a semiconductor package using a general metal wire.

In particular, Korean Patent Application Pub. No. 10-2017-0086828 (a clip bonding semiconductor chip package using a metal bump) discloses that a metal bump is formed on and protrudes from a bonding pad of a semiconductor chip and a clip is joined to the metal bump. However, in such a case, processes such as melting, sputtering, electroplating, and screen printing are needed in forming of the metal bump on the bonding pad and thus, productivity is decreased. Also, since the metal bump is formed of copper (Cu) or gold (Au) that facilitates soldering, a bonding force between the metal bump and the bonding pad is decreased due to each different thermal expansion coefficient and an electric connection property is poor.

### SUMMARY OF THE INVENTION

### Technical Problem

The present invention provides a semiconductor package using a conductive metal structure in which a conductive metal structure is directly soldered on a metal pad formed on an upper part of a semiconductor chip, instead of using an additional metal material such as a general metal bump, wherein the metal pad is prepared to be used in bonding, so that production cost and manufacturing processes may be greatly reduced and a bonding force between a clip and the semiconductor chip may be increased.

### Technical Solution

According to an aspect of the present invention, there is provided a semiconductor package using a conductive metal structure including: a semiconductor chip; an aluminum pad formed on an upper part of the semiconductor chip; and a conductive metal structure adhered to the aluminum pad by a solder-based second adhesive layer, wherein the second adhesive layer includes intermetallic compounds (IMC) distributed to a lower fixed part thereof near the aluminum pad.

The IMCs of the second adhesive layer may include aluminum (Al) and the aluminum (Al) may hold 0.5 to 30 parts by weight with respect to 100 parts by weight of the total IMCs.

When the second adhesive layer is soldered using a solder including tin and when parts by weight of the tin is above 80 parts by weight of the total weight of the solder, aluminum (Al) may hold 0.5 to 30 parts by weight with respect to 100 parts by weight of the total IMCs.

The IMCs may be dispersed and distributed within an area at a height of approximately 30 um based on a boundary surface of the aluminum pad.

When more than 5 parts by weight of aluminum (Al) is included in 100 parts by weight of the IMCs, the maximum height of the IMCs is 30 um

When the second adhesive layer is soldered using a solder including lead and when parts by weight of the lead is above 80 parts by weight of the total weight of the solder, aluminum (Al) may hold 0.5 to 30 parts by weight with respect to 100 parts by weight of the total IMCs.

The IMCs may be densely distributed within an area at a height of approximately 20 um based on a boundary surface of the aluminum pad.

When a thickness D of the aluminum pad, which is before being adhered to the second adhesive layer, is M1≤D≤M2, a thickness D1 of the aluminum pad, which is after being adhered to the second adhesive layer, may be 0≤D1≤(2/3)×M2.

The thickness D1 of the aluminum pad may be 0≤D1≤4 um.

The conductive metal structure may be a clip structure including one end combined to the aluminum pad.

The conductive metal structure may be a column structure including one end combined to the aluminum pad and the other end connected to a board.

The semiconductor package according to the present invention includes a lead frame, the semiconductor chip, the aluminum pad, the clip structure, and a sealing member, wherein the lead frame includes a pad and a lead, the semiconductor chip is adhered to the upper part of the pad included in the lead frame, the aluminum pad is formed on the upper part of the semiconductor chip, the clip structure includes one end combined to the aluminum pad and the other end combined to the lead of the lead frame, and the sealing member is formed to surround the semiconductor chip and the clip structure using molding. A solder or an epoxy resin based first adhesive layer is adhered to an adhering part of the lead frame and a solder-based second adhesive layer is directly adhered to an adhering part interposed between the clip structure and the aluminum pad, wherein the second adhesive layer includes IMCs distributed to a lower fixed part thereof near the aluminum pad.

Also, the semiconductor package according to the present invention includes the lead frame, a first semiconductor chip, a first aluminum pad, a first clip structure, a second semiconductor chip, a second aluminum pad, a second clip structure, and the sealing member, wherein the lead frame includes the pad and the lead, the first semiconductor chip is adhered to the upper part of the pad included in the lead frame, the first aluminum pad is formed on the upper part of the first semiconductor chip, the first clip structure includes one end combined to the first aluminum pad and the other end combined to the lead of the lead frame, the second semiconductor chip is adhered to the upper part of the first clip structure, the second aluminum pad is formed on the upper part of the second semiconductor chip, the second clip structure includes one end combined to the second aluminum pad and the other end combined to the lead of the lead frame, and the sealing member is formed to surround the first and second semiconductor chips and the first and second clip structures using molding. The solder or epoxy resin based first adhesive layer is respectively adhered to an adhering part of the lead frame and an adhering part interposed between the first clip structure and the second semiconductor chip. Also, the solder-based second adhesive layer is adhered to adhering parts interposed between the first and second aluminum pads and the first and second clip structures so that the first and second clip structures are directly adhered to the second adhesive layer. Here, the second adhesive layer includes the IMCs respectively distributed to lower fixed parts thereof near the first and second aluminum pads.

In addition, the semiconductor package according to the present invention includes a lower board and an upper board each having a metal pattern, the semiconductor chip, the aluminum pad, a first column structure, a second column structure, and the sealing member, wherein the lower board and the upper board are spaced apart from each other at a lower part and an upper part of the semiconductor package and face each other, the semiconductor chip is adhered to the upper part of the lower board, the aluminum pad is formed on the upper part of the semiconductor chip, the first column structure is adhered to the aluminum pad and is connected to the upper board, the second column structure is adhered to the metal pattern of the lower board and is connected to the metal pattern of the upper board, and the sealing member is formed to surround the semiconductor chip and the first and second column structures using molding. The solder or epoxy resin based first adhesive layer is adhered to an adhering part of the lower board, and the solder-based second adhesive layer is adhered to an adhering part interposed between the aluminum pad and the first column structure so that the first column structure is directly adhered to the second adhesive layer. Here, the second adhesive layer includes the IMCs distributed to a lower fixed part thereof near the aluminum pad.

According to the present invention, a clip or column type conductive metal structure is adhered to an aluminum pad formed on a semiconductor chip, a separate metal bump is not formed on an aluminum pad as in the conventional art, and the metal structure is directly soldered and adhered on the aluminum pad. Therefore, manufacturing processes may be reduced to increase productivity and a structural problem occurring due to use of the metal bump may be solved to improve durability and an electrical connection property.

### BRIEF DESCRIPTION OF THE DRAWINGS

The above and other features and advantages of the present invention will become more apparent by describing in detail exemplary embodiments thereof with reference to the attached drawings in which:

FIG. 1 illustrates a semiconductor package according to a first embodiment of the present invention;

FIG. 2 illustrates a second adhesive layer of the present invention;

FIG. 3A is an enlarged view showing distribution of intermetallic compounds (IMCs) when tin is a main ingredient of the second adhesive layer;

FIG. 3B is an enlarged view showing that distribution of the IMCs when lead is a main ingredient of the second adhesive layer;

FIG. 4 illustrates that an aluminum metal layer is further formed on a lower part of a clip structure according to an embodiment of the present invention;

FIG. 5 illustrates a semiconductor package according to a second embodiment of the present invention; and

FIG. 6 illustrates a semiconductor package according to a third embodiment of the present invention.

### DETAILED DESCRIPTION OF THE INVENTION

The present invention will now be described more fully with reference to the accompanying drawings, in which exemplary embodiments of the invention are shown. In the description, the detailed descriptions of well-known technologies and structures may be omitted so as not to hinder the understanding of the present invention

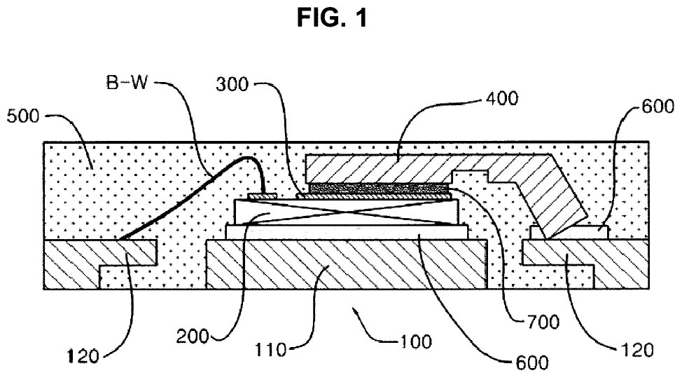

FIG. 1 illustrates a semiconductor package according to a first embodiment of the present invention. As illustrated in FIG. 1, the semiconductor package includes a lead frame 100, a semiconductor chip 200, an aluminum pad 300, a clip structure 400, and a sealing member 500, wherein the lead frame 100 includes a pad 110 and a lead 120, the semiconductor chip 200 is adhered to the upper part of the pad 110 included in the lead frame 100, the aluminum pad 300 is formed on the upper part of the semiconductor chip 200, the clip structure 400 includes one end combined to the aluminum pad 300 and the other end combined to the lead 120 of the lead frame 100, and the sealing member 500 is formed to surround the semiconductor chip 200 and the clip structure 400 using molding.

A solder or an epoxy resin based first adhesive layer 600 is adhered to an adhering part of the lead frame 100 and a solder-based second adhesive layer 700 is directly adhered to an adhering part interposed between the clip structure 400 and the aluminum pad 300, wherein the second adhesive layer 700 includes intermetallic compounds (IMC) 710 distributed to a lower fixed part thereof near the aluminum pad 300.

According to the present invention, a separate metal bump for adhering the aluminum pad 300 to the clip structure 400 is not included and instead, the clip structure 400 is directly soldered on the aluminum pad 300 and adhered to the aluminum pad 300. Accordingly, productivity may be increased and a structural problem occurring due to use of the metal bump may be solved.

The first embodiment above illustrates that one clip structure 400 is adhered. The clip structure 400 is connected to the lead 120 disposed at one end thereof and the lead 120 disposed at the other side of the clip structure 400 is electrically connected to the aluminum pad 300 using a bonding wire B-W.

The lead frame 100 of the first embodiment includes the pad 110, on which the semiconductor chip 200 is placed, and the lead 120 electrically connected to the semiconductor chip 200. Here, the lead frame 100 may be changed into a board having a metal pattern as illustrated in a third embodiment which will be described below.

The aluminum pad 300 is formed on the upper part of the semiconductor chip 200. Since the semiconductor chip 200 is formed for wire bonding, the clip structure 400 may not be directly adhered to the semiconductor chip 200 and thus, the aluminum pad 300 is formed to have a regular thickness. Here, aluminum does not hold the entire weight of the aluminum pad 300 and impurities may be unavoidably contained in the aluminum pad 300. Thus, it may be appropriate that aluminum holds over 95 parts by weight of the entire aluminum pad 300. In order for the aluminum pad 300 of the present invention to form the optimized IMCs 710, the aluminum pad 300 may have a thickness of 1 to 6 μm

The thickness of the aluminum pad 300 denotes a thickness before the clip structure 400 being adhered to the aluminum 300.

After soldering of the second adhesive layer 700, the aluminum pad 300 is melted and diffused to the IMCs 710 and thus, the thickness of the aluminum pad 300 may be reduced to 0 to 4 μm.

The thickness of the aluminum pad 300 will be described in more detail below.

It is assumed that an initial thickness of the aluminum pad 300, which is before soldering, is D and a thickness changed after soldering is D1.

When the thickness D is in the range of M1≤D≤M2 and the thickness D1 is in the range of 0≤D1≤(2/3)×M2, it is discovered that soldering is efficiently accomplished.

Here, 0 denotes that the aluminum pad 300 is completely melted and (2/3)×M2 denotes a maximum soluble range when the thickness of the aluminum pad 300 is the thickest in the corresponding range.

Accordingly, as described above, when the range of the thickness D is 1≤D≤6, the range of the thickness D1 is 0≤D1≤4.

Therefore, when the thicknesses D and D1 of the aluminum pad 300 are in the above ranges, outstanding effect may be achieved in the present invention.

The clip structure 400 is a metal structure used to electrically connect the semiconductor chip 200 to the lead 120 of the lead frame 100 and is formed of a single metal such as copper (Cu) as a main ingredient or a metal mixture formed by partly mixing impurities added to change a property of copper (Cu) such as silicon (Si), nickel (Ni), phosphorus (P), zinc (Zn), iron (Fe), lead (Pb), manganese (Mn), tin (Sn), and chrome (Cr) to copper (cu).

An adhesive layer of the present invention may be formed in 2 types. That is, the first adhesive layer 600 is applied to an adhering part of the lead frame 100 and the second adhesive layer 700 is applied to adhering parts of the aluminum pad 300 and the clip structure 400. The first adhesive layer 600 may be formed of a solder or epoxy resin based conductive adhesive and a type of the adhesive is not restricted if electrical connection is available.

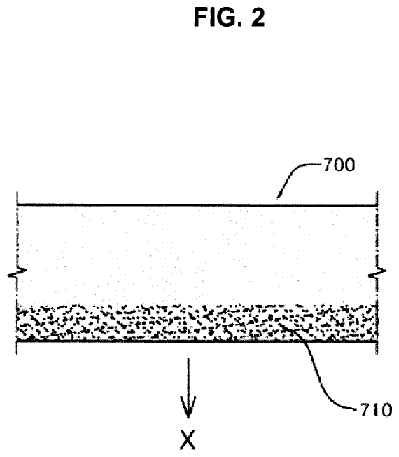

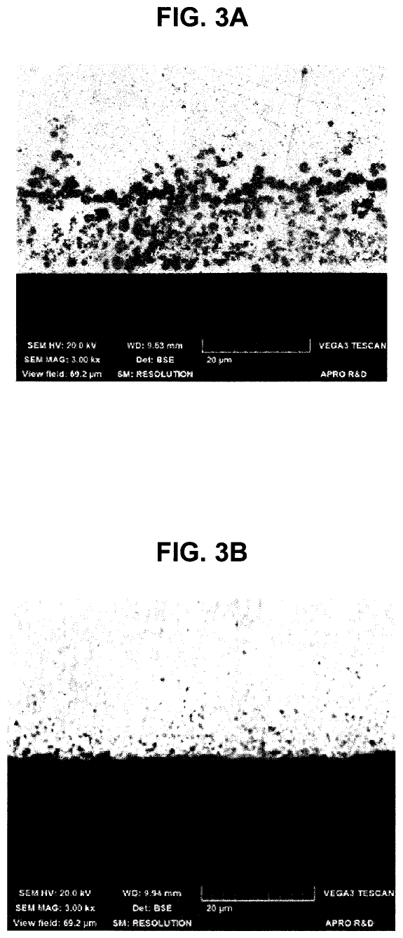

However, the second adhesive layer 700 may be formed of a solder-based adhesive only. An epoxy resin based conductive adhesive may not be used in the second adhesive layer 700, since the IMCs 710 may not be produced during an adhering process. Accordingly, the IMCs 710 illustrated in FIGS. 2 through 3 are only formed in the second adhesive layer 700.

The IMCs 710 are distributed to a lower fixed part corresponding to a part X near the aluminum pad 300 within the second adhesive layer 700 and are manufactured by an interface reaction between a metal material separated after melting a part of the aluminum pad 300 at above a specific temperature and metal components included in a solder. The IMCs 710 may partly include materials corresponding to the metal components included in a solder. However, according to the present invention, the IMCs 710 include a certain amount of an aluminum (Al) component.

Since the IMCs 710 including aluminum (Al) distributed to the second adhesive layer 700 have metallic characteristics similar to those of the aluminum pad 300, a structural stress occurring due to a thermal expansion coefficient may be reduced, and durability and an electrical connection property may be improved.

The inventor identifies that when the aluminum pad 300 and the clip structure 400 are adhered to each other by soldering, when the second adhesive layer 700 is soldered using a solder including tin, and when parts by weight of the tin is above 80 parts by weight of the total weight of the solder, aluminum (Al) holds 0.5 to 30 parts by weight with respect to 100 parts by weight of the total IMCs 710. Here, the IMCs 710 are dispersed and distributed within an area at a height of approximately 30 um based on a boundary surface of the aluminum pad 300. In particular, when more than 5 parts by weight of aluminum (Al) is included in the IMCs 710, the maximum height of the IMCs 710 is 30 um or below so that the IMCs 710 may be appropriately balanced and distributed and a bonding force is excellent.

Also, the inventor identifies that when the aluminum pad 300 and the clip structure 400 are adhered to each other by soldering, when the second adhesive layer 700 is soldered using a solder including lead, and when parts by weight of the lead is above 80 parts by weight of the total weight of the solder, aluminum (Al) holds 0.5 to 30 parts by weight with respect to 100 parts by weight of the total IMCs 710. Here, as illustrated in FIG. 3B, the IMCs 710 are densely distributed within an area at a height of approximately 20 um based on a boundary surface of the aluminum pad 300.

When a main component of a soldering adhesive varies or a content ratio of the soldering adhesive varies, the ratio of aluminum (Al) in the IMCs 710 may be 0.5 to 30 parts by weight with respect to 100 parts by weight of the total IMCs 710. However, when the ratio of aluminum (Al) in the IMCs 710 is below 0.5 parts by weight, effect regarding an adhering property may not be properly shown, and when the ratio of aluminum (Al) in the IMCs 710 is above 30 parts by weight, hardness of an adhering part lowers by an excessive aluminum (Al) component and a bonding force rather decreases.

In the present invention, in order to form the aluminum (Al) component of the IMCs 710, the second adhesive layer 700 may further include a melting facilitator so that soldering may be smoothly accomplished. Examples of the melting facilitator may include a certain amount of stibium (Sb), wherein the stibium (Sb) effectively melts the aluminum pad 300 under the soldering condition of 200 to 300° C. so that an aluminum (Al) component may be included in the IMCs 710.

Since a general adhesive does not include such a melting facilitator and thus, melting of a bonding pad formed of aluminum (Al) is not smoothly accomplished, metal bumps formed of metals such as Ag, Au, or Pb are included to perform soldering. Accordingly, in the present invention, the second adhesive layer 700 further includes a melting facilitator used to facilitate melting of the aluminum pad 300 so that the clip structure 400 may be directly adhered to the aluminum pad 300 without using additional metal bumps and a bonding property may be improved by aluminum included in the IMCs 710.

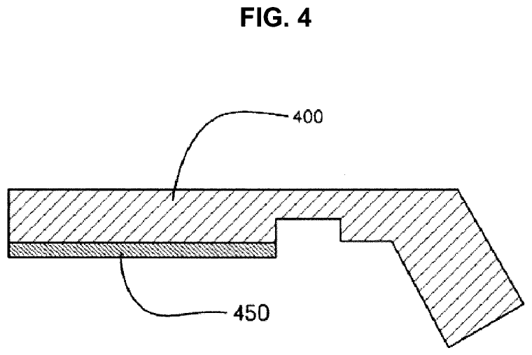

In addition, FIG. 4 illustrates the clip structure 400 according to another embodiment of the present invention, wherein the clip structure 400 formed of copper (Cu) further includes an aluminum metal layer 450 on a lower part thereof, that is, a part contacting the second adhesive layer 700 and thus, has the same metallic characteristic as that of the aluminum pad 300. Therefore, a bonding force may be increased.

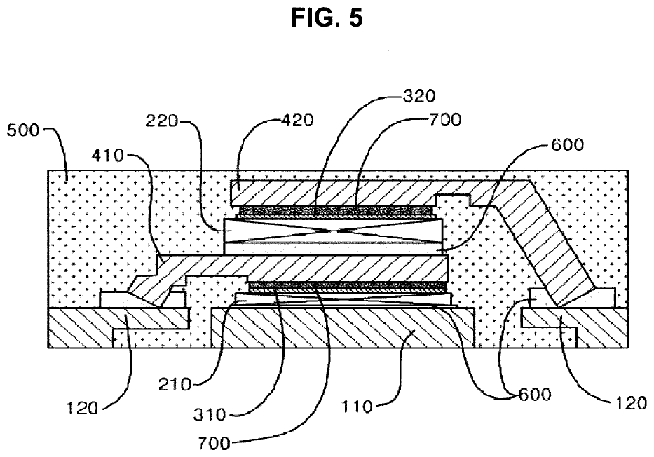

FIG. 5 illustrates a semiconductor package according to a second embodiment of the present invention, wherein two semiconductor chips and two clip structures are stacked. More specifically, the semiconductor package according to the second embodiment of the present invention includes the lead frame 100, a first semiconductor chip 210, a first aluminum pad 310, a first clip structure 410, a second semiconductor chip 220, a second aluminum pad 320, a second clip structure 420, and the sealing member 500, wherein the lead frame 100 includes the pad 110 and the lead 120, the first semiconductor chip 210 is adhered to the upper part of the pad 110 included in the lead frame 100, the first aluminum pad 310 is formed on the upper part of the first semiconductor chip 210, the first clip structure 410 includes one end combined to the first aluminum pad 310 and the other end combined to the lead 120 of the lead frame 100, the second semiconductor chip 220 is adhered to the upper part of the first clip structure 410, the second aluminum pad 320 is formed on the upper part of the second semiconductor chip 220, the second clip structure 420 includes one end combined to the second aluminum pad 320 and the other end combined to the lead 120 of the lead frame 100, and the sealing member 500 is formed to surround the first and second semiconductor chips 210 and 220 and the first and second clip structures 410 and 420 using molding.

The solder or epoxy resin based first adhesive layer 600 is respectively adhered to an adhering part of the lead frame 100 and an adhering part interposed between the first clip structure 410 and the second semiconductor chip 220. Also, the solder-based second adhesive layer 700 is adhered to adhering parts interposed between the first and second aluminum pads 310 and 320 and the first and second clip structures 410 and 420 so that the first and second clip structures 410 and 420 are directly adhered to the second adhesive layer 700. Here, the second adhesive layer 700 includes the IMCs 710 respectively distributed to lower fixed parts thereof near the first and second aluminum pads 310 and 320.

Similar to the first embodiment, the IMCs 710 of the second adhesive layer 700 in the second embodiment include aluminum (Al). Characteristics of the second adhesive layer 700 illustrated in the first and second embodiments are the same as those of the second adhesive layer 700 in a third embodiment, which will be described later. Also, characteristics regarding a thickness of the aluminum pad 300 are applied in common in the second and third embodiments and thus, repetitive descriptions will be omitted.

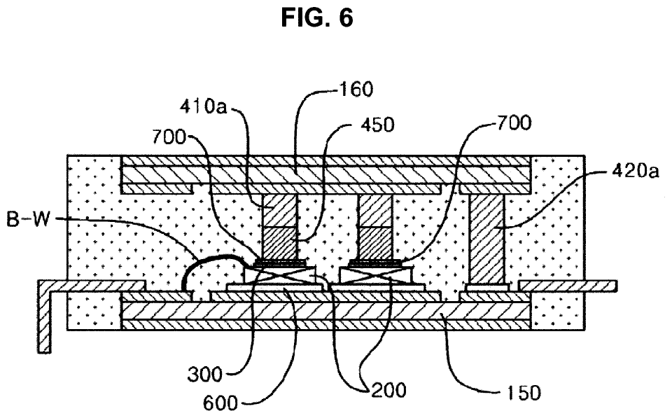

FIG. 6 illustrates a semiconductor package according to a third embodiment of the present invention, wherein electrical connection is accomplished through a column type metal structure, instead of the clip type metal structure. More specifically, the semiconductor package according to the third embodiment of the present invention includes a lower board 150 and an upper board 160 each having a metal pattern, the semiconductor chip 200, the aluminum pad 300, a first column structure 410a, a second column structure 420a, and the sealing member 500, wherein the lower board 150 and the upper board 160 are spaced apart from each other at a lower part and an upper part of the semiconductor package and face each other, the semiconductor chip 200 is adhered to the upper part of the lower board 150, the aluminum pad 300 is formed on the upper part of the semiconductor chip 200, the first column structure 410a is adhered to the aluminum pad 300 and is connected to the upper board 160, the second column structure 420a is adhered to the metal pattern of the lower board 150 and is connected to the metal pattern of the upper board 160, and the sealing member 500 is formed to surround the semiconductor chip 200 and the first and second column structures 410a and 420a using molding.

The solder or epoxy resin based first adhesive layer 600 is adhered to an adhering part of the lower board 150, and the solder-based second adhesive layer 700 is adhered to an adhering part interposed between the aluminum pad 300 and the first column structure 410a so that the first column structure 410a is directly adhered to the second adhesive layer 700. Here, the second adhesive layer 700 includes the IMCs 710 distributed to a lower fixed part thereof near the aluminum pad 300.

The first and second column structures 410a and 420a may be formed of a metal including copper (Cu) as a main component, as in the same manner as in the clip structure 400 of the first and second embodiments described above. However, as illustrated in the drawing, the first column structure 410a, where the second adhesive layer 700 is applied, may include the aluminum metal layer 450 on the lower part thereof and a copper layer on the upper part thereof. Thus, the first column structure 410a may be formed of a metal combination including each different metal. Since the first column structure 410a is formed as described above, a metallic characteristic of the aluminum layer 450 of the first column structure 410a is same as that of the aluminum pad 300 disposed at the lower part of the aluminum layer 450 and thus, a bonding force may be increased.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A semiconductor package using a conductive metal structure, the semiconductor package comprising:
a semiconductor chip;
an aluminum pad formed on an upper part of the semiconductor chip; and
a conductive metal structure adhered to the aluminum pad by a solder-based second adhesive layer,
wherein the second adhesive layer comprises intermetallic compounds (IMC) distributed to a lower fixed part thereof near the aluminum pad.

2. The semiconductor package of claim 1, wherein the IMCs of the second adhesive layer comprise aluminum (Al) and the aluminum (Al) holds 0.5 to 30 parts by weight with respect to 100 parts by weight of the total IMCs.

3. The semiconductor package of claim 1, wherein when the second adhesive layer is soldered using a solder comprising tin and when parts by weight of the tin is above 80 parts by weight of the total weight of the solder, aluminum (Al) holds 0.5 to 30 parts by weight with respect to 100 parts by weight of the total IMCs.

4. The semiconductor package of claim 3, wherein the IMCs are dispersed and distributed within an area at a height of approximately 30 um based on a boundary surface of the aluminum pad.

5. The semiconductor package of claim 1, wherein when the second adhesive layer is soldered using a solder comprising lead and when parts by weight of the lead is above 80 parts by weight of the total weight of the solder, aluminum (Al) holds 0.5 to 30 parts by weight with respect to 100 parts by weight of the total IMCs.

6. The semiconductor package of claim 5, wherein the IMCs are densely distributed within an area at a height of approximately 20 um based on a boundary surface of the aluminum pad.

7. The semiconductor package of claim 1, wherein when a thickness D of the aluminum pad, which is before being adhered to the second adhesive layer, is M1≤D≤M2, a thickness D1 of the aluminum pad, which is after being adhered to the second adhesive layer, is 0≤D1≤(2/3)×M2.

8. The semiconductor package of claim 7, wherein the thickness D1 of the aluminum pad is 0≤D1≤4 um.

9. The semiconductor package of claim 1, wherein the conductive metal structure is a clip structure comprising one end combined to the aluminum pad.

10. The semiconductor package of claim 1, wherein the conductive metal structure is a column structure comprising one end combined to the aluminum pad and the other end connected to a board.

11. The semiconductor package of claim 4, wherein when more than 5 parts by weight of aluminum (Al) is included in 100 parts by weight of the IMCs, the maximum height of the IMCs is 30 um.

12. The semiconductor package of claim 2, wherein when a thickness D of the aluminum pad, which is before being adhered to the second adhesive layer, is M1≤D≤M2, a thickness D1 of the aluminum pad, which is after being adhered to the second adhesive layer, is 0≤D1≤(2/3)×M2.

13. The semiconductor package of claim 3, wherein when a thickness D of the aluminum pad, which is before being adhered to the second adhesive layer, is M1≤D≤M2, a thickness D1 of the aluminum pad, which is after being adhered to the second adhesive layer, is 0≤D1≤(2/3)×M2.

14. The semiconductor package of claim 5, wherein when a thickness D of the aluminum pad, which is before being adhered to the second adhesive layer, is M1≤D≤M2, a thickness D1 of the aluminum pad, which is after being adhered to the second adhesive layer, is 0≤D1≤(2/3)×M2.

15. The semiconductor package of claim 12, wherein the thickness D1 of the aluminum pad is 0≤D1≤4 um.

16. The semiconductor package of claim 13, wherein the thickness D1 of the aluminum pad is 0≤D1≤4 um.

17. The semiconductor package of claim 14, wherein the thickness D1 of the aluminum pad is 0≤D1≤4 um.

18. The semiconductor package of claim 2, wherein the conductive metal structure is a clip structure comprising one end combined to the aluminum pad.

19. The semiconductor package of claim 2, wherein the conductive metal structure is a column structure comprising one end combined to the aluminum pad and the other end connected to a board.
